(19) United States
(12) Patent Application Publication
(10) Pub. No.: US 2026/0238175 A1
(43) Pub. Date: Aug. 13, 2026

(54) High-frequency filter

(71) Applicant: Nisshinbo Micro Devices Inc., Tokyo (JP)

(72) Inventor: Yasuhiro Tsukada, Fujimino-shi (JP)

(21) Appl. No.: 19/154,713

(22) PCT Filed: Feb. 28, 2023
(86) PCT No.: PCT/JP2023/007382

§ 371 Date: Aug. 7, 2025

(51) Int. Cl. H03H 7/01; H01P 1/20

(52) U.S. Cl. CPC H03H 7/0115; H01P 1/20

(57) ABSTRACT

Provided is a high-frequency filter comprising, on a surface of a dielectric substrate, transmission lines connected to two terminals that serve as an input terminal or an output terminal for a high-frequency signal, respectively, and lumped constant elements connected in series between these transmission lines, the lumped constant elements being composed of capacitors, the number of capacitors and their capacitances being set to predetermined values, and the capacitors being connected to each other, respectively, by transmission lines having a line length of λ/4 and a characteristic impedance of Z₀, so that the high-frequency filter does not require any lumped constant elements connected to a ground plane and any through holes connecting these lumped constant elements and the ground plane.

### TECHNICAL FIELD

The present invention relates to a high-frequency filter that filters a signal in a specific frequency band from a high-frequency signal.

### BACKGROUND ART

An LC filter configured by combining a capacitor and an inductor, which are lumped constant elements, can constitute a high-pass filter and a low-pass filter by changing arrangements of the capacitor and the inductor, and a band-pass filter can be also constituted by combining these high-pass and low-pass filters. For example, Patent Document 1 describes a low-pass filter that is constituted with an LC filter.

FIG. 13 is an explanatory view showing one example of a lumped constant type high-pass filter constituted with a general LC filter. As shown in FIG. 13, a capacitor C_{H} is connected between transmission lines TL connected to two terminals P1 and P2 that serve as an input terminal or an output terminal for a high-frequency signal, respectively, and an inductor L_{H} is connected between each of the transmission line TL between the terminal P1 and the capacitor C_{H} and the transmission line TL between the terminal P2 and the capacitor C_{H} and ground.

FIG. 14 is a characteristic diagram showing frequency characteristics of a reflection loss and an insertion loss when a frequency f₀, at which a reflection loss within a passband frequency is minimized, is set to 10 GHz, a capacitance C(H) of the capacitor C_{H} is set as C(H)=1/(2π·f₀·Z₀) (Z₀ is a characteristic impedance), and an inductance L(H) of the inductor L_{H} is set as L(H)=Z₀/(2π·f₀), in one example of the high-pass filter shown in FIG. 13. In FIG. 14, the dashed line indicates a frequency characteristic of the reflection loss, and the solid line indicates a frequency characteristic of the insertion loss. When a frequency, at which the insertion loss drops by 0.5 dB, is defined as a cutoff frequency, the cutoff frequency is 8.0 GHz in the example shown in FIG. 14, and a high-pass filter is configured in which a frequency band exceeding the cutoff frequency is defined as a passband.

In addition, FIG. 15 is an explanatory view showing one example of a lumped constant type low-pass filter constituted with a general LC filter. As shown in FIG. 15, an inductor L_{L} is connected between transmission lines TL connected to two terminals P1 and P2 that serve as an input terminal or an output terminal for a high-frequency signal, respectively, and a capacitor C_{L} is connected between each of the transmission line TL between the terminal P1 and the inductor L_{L} and the transmission line TL between the terminal P2 and the inductor L_{L} and ground.

FIG. 16 is a characteristic diagram showing frequency characteristics of a reflection loss and an insertion loss when a frequency f₀, at which a reflection loss within a passband frequency is minimized, is set to 10 GHz, an inductance L(L) of the inductor L_{L} is set to as L(L)=Z₀/(2π·f₀), and a capacitance C(L) of the capacitor C_{L} is set as C(L)=1/(2π·f₀·Z₀), in one example of the low pass filter shown in FIG. 15. In FIG. 16, the dashed line indicates a frequency characteristic of the reflection loss, and the solid line indicates a frequency characteristic of the insertion loss. When a frequency, at which the insertion loss drops by 0.5 dB, is defined as a cutoff frequency, the cutoff frequency is 12.5 GHz in the example shown in FIG. 16, and a low-pass filter is configured in which a frequency band below the cutoff frequency is defined as a passband.

Moreover, a band-pass filter can also be configured by connecting the high-pass filter shown in FIG. 13 and the low-pass filter shown in FIG. 15 in series.

### PRIOR ART DOCUMENT

### Patent Document

Patent Document 1: JP 2005-354446 A

### SUMMARY OF THE INVENTION

### Problem to be Solved by the Invention

A high-frequency filter used in a high-frequency band such as a microwave band and a millimeter wave band uses a distributed constant transmission line such as a microstrip line, and a transmission line of a high-frequency signal and lumped constant elements of a capacitor, an inductor, and the like are arranged on a surface of a dielectric substrate. Here, some of the lumped constant elements of the capacitor, the inductor, and the like are connected to a ground plane provided on the rear surface of the dielectric substrate via through holes formed through the dielectric substrate and are grounded.

For example, when configuring a high-frequency filter equivalent to the high-pass filter shown in FIG. 13 with microstrip lines, transmission lines composed of microstrip lines connected to the first terminal P1 and the second terminal P2, respectively, are arranged on the surface of the dielectric substrate, and the capacitor C_{H}, which is a chip component, is connected between these transmission lines. Two inductors L_{H}, which are chip components, each have one terminal connected to the transmission line that is connected to the first terminal P1 and one terminal of the capacitor C_{H} or the transmission line that is connected to the second terminal P2 and the other terminal of the capacitor C_{H}, and another terminal connected to transmission lines that are connected to the through holes. These transmission lines are connected via the through holes to the ground plane arranged on the rear surface of the dielectric substrate.

Similarly, for example, when configuring a high-frequency filter equivalent to the low-pass filter shown in FIG. 15 with microstrip lines, transmission lines composed of microstrip lines connected to the first terminal P1 or the second terminal P2, respectively, are arranged on the surface of the dielectric substrate, and the inductor L_{L}, which is a chip component, is connected between these transmission lines. Two capacitors C_{L}, which are chip components, each have one terminal connected to the transmission line that is connected to the first terminal P1 and one terminal of the inductor L_{L} or the transmission line that is connected to the second terminal P2 and the other terminal of the inductor L_{L}, and another terminal connected to transmission lines that are connected to the through holes. These transmission lines are connected via the through holes to the ground plane arranged on the rear surface of the dielectric substrate.

In the meantime, the above-described through-hole can be regarded as an inductor having a physical quantity equivalent to a thickness of the dielectric substrate. For example, in the configuration as shown in FIG. 13, as a result of connecting the through holes (inductors) in series to the inductor L_{H}, an increase in apparent inductance increases impedance, and the frequency, at which the reflection loss is minimized, is lowered compared to a case where there is no through hole. This lowers the cutoff frequency, hindering high-frequency adaptation.

Moreover, in the configuration as shown in FIG. 15, the through holes (inductors) are connected in series to the capacitor C_{L}, so that a self-resonant frequency of a series circuit of the capacitor C_{L} and the inductors composed of the through holes is lowered. In a frequency band above this self-resonant frequency, impedance is increased, and the frequency, at which the reflection loss is minimized, is lowered. This lowers the cutoff frequency, hindering high-frequency adaptation of the high-frequency filter.

Therefore, it is an object of the present invention to provide a high-frequency filter that does not require a lumped constant element connected to a ground plane, which hinders high-frequency adaptation, and a through-hole connecting this lumped constant element and the ground plane.

### Means to Solve the Problem

(1) The first embodiment of the high-frequency filter of the present invention is a high-frequency filter comprising, on a surface of a dielectric substrate, transmission lines connected to a first terminal and a second terminal, respectively, and 2n−1 (n is an integer of 2 or more) lumped constant elements connected in series between the transmission lines, one end of a first lumped constant element being connected to the first terminal, one end of a 2n−1-th lumped constant element being connected to the second terminal, and a second to a 2n−2-th lumped constant elements being connected between the first lumped constant element and the 2n−1-th lumped constant element, wherein all of the 2n−1 lumped constant elements are composed of capacitors, the capacitors being connected to each other by a transmission line having a line length of λ/4 (λ is a wavelength within a transmission line corresponding to a frequency f₀ at which a reflection loss of a passband frequency is minimized) and a characteristic impedance of Z₀, and wherein (i) when n is 2, a capacitance C(H1) of the capacitors is C(H1)=1/(2π·f₀·Z₀), and (ii) when n is 3 or more, a capacitance C(H2) of a 2x−1-th (x is an integer from 2 to (n−1)) one of the capacitors from the first terminal is C(H2)=½(2π·f₀·Z₀), and a capacitance C(H3) of the capacitors other than the 2x−1-th one from the first terminal is C(H3)=1/(2π·f₀·Z₀).
(2) Another second embodiment of the high-frequency filter of the present invention is a high-frequency filter comprising, on a surface of a dielectric substrate, transmission lines connected to a first terminal and a second terminal, respectively, and 2n−1 (n is an integer of 2 or more) lumped constant elements connected in series between the transmission lines, one end of a first lumped constant element being connected to the first terminal, one end of a 2n−1-th lumped constant element being connected to the second terminal, and a second to a 2n−2-th lumped constant elements being connected between the first lumped constant element and the 2n−1-th lumped constant element, wherein all of the 2n−1 lumped constant elements are composed of inductors, the inductors being connected to each other by a transmission line having a line length of λ/4 (λ is a wavelength within a transmission line corresponding to a frequency f₀ at which a reflection loss of a passband frequency is minimized) and a characteristic impedance of Z₀, and wherein (i) when n is 2, an inductance L(L1) of the inductors is L(L1)=Z₀(2π·f₀), and (ii) when n is 3 or more, an inductance L(L2) of a 2x−1-th (x is an integer from 2 to (n−1)) one of the inductors from the first terminal is L(L2)=2Z₀/(2π·f₀), and an inductance L(L3) of the inductors other than the 2x−1-th one from the first terminal is L(L3)=Z₀/(2π·f₀).
(3) Another third embodiment of the high-frequency filter of the present invention is a high-frequency filter in which the high-frequency filter of (1) above and the high-frequency filter of (2) above are connected in series.

### Effect of the Invention

According to the high-frequency filter of the present invention, on the surface of the dielectric substrate, transmission lines connected to two terminals that serve as an input terminal or an output terminal for a high-frequency signal, respectively, and lumped constant elements connected in series between these transmission lines are provided, the lumped constant elements being composed of capacitors or inductors, the number of capacitors and their capacitances or the number of inductors and their inductances being set to predetermined values, and adjacent capacitors or inductors being connected to each other, respectively, by transmission lines having a line length of λ/4 and a characteristic impedance of Z₀, thereby making it possible to achieve a configuration that does not require any lumped constant elements connected to a ground plane and any through holes connecting these lumped constant elements and the ground plane. In this way, no lumped constant elements and no through holes are required which hinder high-frequency adaptation of the high-frequency filter, which, as a result, makes it possible to realize high-frequency adaptation of the high-frequency filter.

### BRIEF DESCRIPTION OF THE DRAWINGS

FIG. 1 is a view explaining a high-frequency filter as a high-pass filter that is one embodiment (Embodiment 1) of the first embodiment of the present invention.

FIG. 2 is a view explaining impedance characteristics of the high-frequency filter of Embodiment 1.

FIG. 3 is a Smith chart showing impedance characteristics of the high-frequency filter of Embodiment 1.

FIG. 4 is a characteristic diagram showing frequency characteristics of a reflection loss and an insertion loss of the high-frequency filter of Embodiment 1.

FIG. 5 is a view explaining a high-frequency filter as a high-pass filter that is another embodiment (Embodiment 2) of the first embodiment of the present invention.

FIG. 6 is a characteristic diagram showing frequency characteristics of a reflection loss and an insertion loss of the high-frequency filter of Embodiment 2.

FIG. 7 is a view explaining a high-frequency filter as a low-pass filter that is one embodiment (Embodiment 3) of the second embodiment of the present invention.

FIG. 8 is a characteristic diagram showing frequency characteristics of a reflection loss and an insertion loss of the high-frequency filter of Embodiment 3.

FIG. 9 is a view explaining a high-frequency filter as a low-pass filter that is another embodiment (Embodiment 4) of the second embodiment of the present invention.

FIG. 10 is a characteristic diagram showing frequency characteristics of a reflection loss and an insertion loss of the high-frequency filter of Embodiment 4.

FIG. 11 is a view explaining a high-frequency filter as a band-pass filter that is one embodiment (Embodiment 5) of the third embodiment of the present invention.

FIG. 12 is a characteristic diagram showing frequency characteristics of a reflection loss and an insertion loss of the high-frequency filter of Embodiment 5.

FIG. 13 is an explanatory view of a lumped constant type high-pass filter constituted with a general LC filter.

FIG. 14 is a characteristic diagram showing frequency characteristics of a reflection loss and an insertion loss of one example of the high-pass filter of FIG. 13.

FIG. 15 is an explanatory view of a lumped constant type low-pass filter constituted with a general LC filter.

FIG. 16 is a characteristic diagram showing frequency characteristics of a reflection loss and an insertion loss of one example of the low-pass filter of FIG. 15.

### EMBODIMENT FOR CARRYING OUT THE INVENTION

The high-frequency filter of the present invention will be described with reference to the drawings. However, the present invention is not limited to these embodiments, and the high-frequency filter can be modified in various ways within the scope of the spirit of the present invention. Moreover, in the drawings, the same reference numerals indicate the equivalent or same ones.

The high-frequency filter of the present invention comprises, on a surface of a dielectric substrate, transmission lines connected to two terminals that serve as an input terminal or an output terminal for a high-frequency signal, respectively, and lumped constant elements connected in series between these transmission lines, the lumped constant elements being composed of capacitors or inductors, the number of capacitors and their capacitances or the number of inductors and their inductances being set to predetermined values, and adjacent capacitors or adjacent inductors being connected to each other, respectively; by transmission lines having a line length of λ/4 (λ is a wavelength within a transmission line corresponding to a frequency f₀ at which a reflection loss of a passband frequency is minimized) and a characteristic impedance of Z₀, thereby making it possible to achieve a configuration that does not require any lumped constant elements connected to a ground plane and any through holes connecting these lumped constant elements and the ground plane.

### Embodiment 1

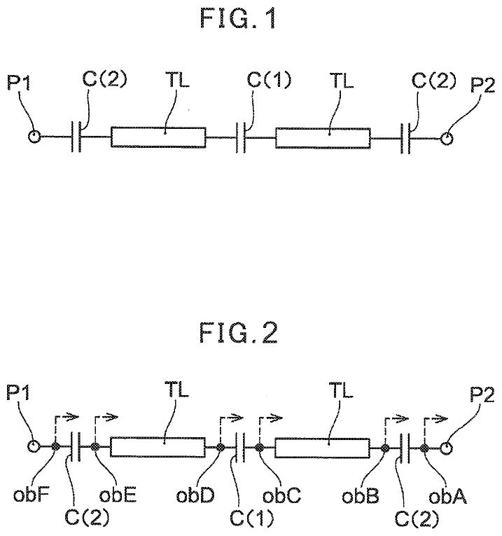

First, Embodiment 1 of the present invention will be described. In the present embodiment, the number of lumped constant elements is 2n−1 (here n is 2), that is, three, and all of the lumped constant elements become high-frequency filters composed of capacitors. FIG. 1 is an explanatory view of a high-frequency filter as a high-pass filter of Embodiment 1 of the present invention, and is an equivalent circuit of the high-frequency filter as the high-pass filter. As shown in FIG. 1, the high-frequency filter of the present embodiment is a matched high-pass filter, in which three capacitors are connected in series between transmission lines connected to a first terminal P1 and a second terminal P2 that serve as an input terminal or an output terminal for a high-frequency signal, respectively. The three capacitors are composed of one capacitor C(1) and two capacitors C(2) connected to both ends of the capacitor C(1). The first terminal P1 and the second terminal P2 are connected to the capacitors. C(2), respectively, by a transmission line having a characteristic impedance of Z₀. The three capacitors are connected to each other by a transmission line TL having a line length of λ/4 and a characteristic impedance of Z₀.

Here, capacitances C1 and C2 of the capacitors C(1) and C(2) are set as follows. First, an ABCD matrix of the high-frequency filter shown in FIG. 1 can be expressed as follows:

$$[ \begin{matrix}A & B \\ C & D\end{matrix} ] = [ \begin{matrix}1 & 1 / ( j ω C 2 {Z}_{0} ) \\ 0 & 1\end{matrix} ] [ \begin{matrix}0 & - j \\ - j & 0\end{matrix} ] [ \begin{matrix}1 & 1 / ( j ω C 1 {Z}_{0} ) \\ 0 & 1\end{matrix} ] [ \begin{matrix}0 & - j \\ - j & 0\end{matrix} ] [ \begin{matrix}1 & 1 / ( j ω C 2 {Z}_{0} ) \\ 0 & 1\end{matrix} ]$$

where j is an imaginary unit and ω=2π·f₀.

Moreover, an ABCD matrix of the high-pass filter shown in FIG. 13 can be expressed as follows:

$$[ \begin{matrix}{A}^{′} & {B}^{′} \\ {C}^{′} & {D}^{′}\end{matrix} ] = [ \begin{matrix}1 & 0 \\ {Z}_{0} / ( j ω L ) & 1\end{matrix} ] [ \begin{matrix}1 & 1 / ( j ω {CZ}_{0} ) \\ 0 & 1\end{matrix} ] [ \begin{matrix}1 & 0 \\ {Z}_{0} / ( j ω L ) & 1\end{matrix} ]$$

where L is an inductance of an inductor L_{H}, and C is a capacitance of a capacitor C_{H}.

Given that insertion losses of the high-frequency filter of the present embodiment and of the high-pass filter shown in FIG. 13 are the same, then |A+B+C+D|=|A′+B′+C′+D′|. Moreover, for perfect matching at frequency f₀, A+B=C+D and A′+B′=C′+D′.

The following relations are derived from the relations above:

$$C 1 = C$$

$$C 2 = L / {Z}_{0}^{2}$$

On the other hand, the capacitance C of the capacitor and the inductance L of the inductor of the high-pass filter shown in FIG. 13 are given by:

$$C = 1 / ( 2 π \cdot {f}_{0} \cdot {Z}_{0} )$$

$$L = {Z}_{0} / ( 2 π \cdot {f}_{0} )$$

thus, the respective capacitances C1 and C2 of the capacitors C(1) and C(2) of the high-frequency filter of the present embodiment are given by:

$$C 1 = C = 1 / ( 2 π \cdot {f}_{0} \cdot {Z}_{0} )$$

$$\begin{matrix}C 2 = L / {Z}_{0}^{2} = ( {Z}_{0} / ( 2 π \cdot {f}_{0} ) ) / {Z}_{0}^{2} \\ = 1 / ( 2 π \cdot {f}_{0} \cdot {Z}_{0} ) = C 1 .\end{matrix}$$

In this way, the respective capacitances C1 and C2 of the capacitors C(1) and C(2) of the high-frequency filter of the present embodiment become equal values. Besides, the capacitances C1 and C2 correspond to the capacitance C(H1) described in the first embodiment of the present invention in (1) mentioned above.

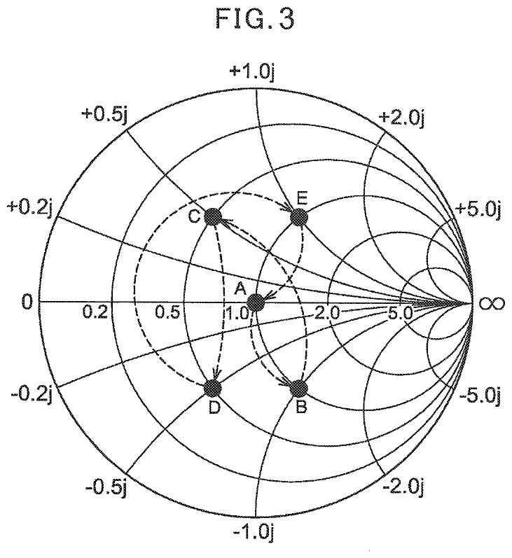

FIG. 2 is a view explaining impedance characteristics of the high-frequency filter of the present embodiment. FIG. 3 is a Smith chart showing impedance characteristics of the high-frequency filter of the present embodiment. In FIG. 2, the first terminal P1 and the second terminal P2 are connected to a matching circuit having a characteristic impedance of Z₀, and an impedance when viewing the second terminal 2P from a connection point obA between a transmission line to which the second terminal 2P is connected and the capacitor C(2) coincides with a characteristic impedance of Z₀ of the transmission line, and becomes an impedance Z_{A} shown at the point A on the Smith chart shown in FIG. 3. Similarly, an impedance when viewing a direction of the second terminal P2 from a connection point obB between the capacitor C(2) and a transmission line TL having a line length of λ/4 and a characteristic impedance of Z₀ becomes an impedance Z_{B} shown at the point B, an impedance when viewing the direction of the second terminal 2P from a connection point obC between the transmission line TL having the line length of λ/4 and the characteristic impedance of Z₀ and the capacitor C(1) becomes an impedance Z_{C} shown at the point C, an impedance when viewing the direction of the second terminal 2P from a connection point obD between the capacitor C(1) and the transmission line TL having the line length of λ/4 and the characteristic impedance of Z₀ becomes an impedance Z_{D} shown at the point D, an impedance when viewing the direction of the second terminal P2 from a connection point obE between the transmission line TL having the line length of λ/4 and the characteristic impedance of Z₀ and the capacitor C(2) becomes an impedance Z_{E} shown at the point E, and an impedance when viewing the direction of the second terminal 2P from a connection point obF between the capacitor C(2) and a transmission line to which the first terminal P1 is connected becomes an impedance Z_{F} shown at the point F. It can be seen that this impedance Z_{F} coincides with the impedance Z_{A}, which coincides with the characteristic impedance of Z₀.

In this way, three capacitors having predetermined capacitances are configured to be connected in series between the transmission lines connected to the first terminal P1 and the second terminal P2, respectively, and the capacitors are configured to be connected to each other by the transmission line having the line length of λ/4 and the characteristic impedance of Z₀, so that a high-frequency filter that serves as a matched high-pass filter can be configured.

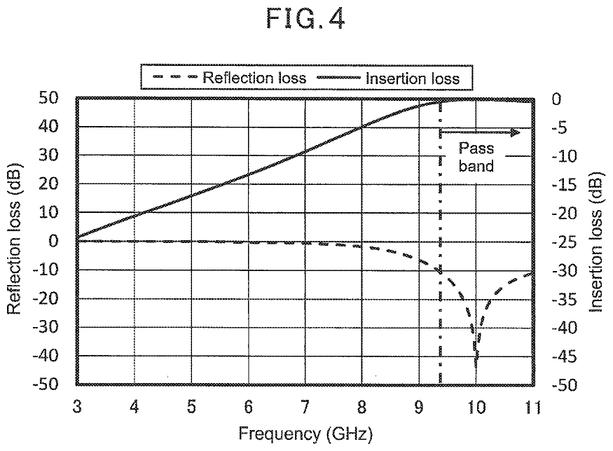

FIG. 4 is a characteristic diagram showing frequency characteristics of a reflection loss and an insertion loss of the high-frequency filter of the present embodiment in which a frequency f₀, at which a reflection loss of a passband frequency is minimized, is set to 10 GHz. In FIG. 4, the dashed line indicates a frequency characteristic of the reflection loss, and the solid line indicates a frequency characteristic of the insertion loss. When the frequency, at which the insertion loss drops by 0.5 dB, is defined as a cutoff frequency, the cutoff frequency becomes 9.4 GHz in the example shown in FIG. 4, and it can be confirmed that a high-frequency filter that functions as a high-pass filter is formed.

Moreover, the high-frequency filter of the present embodiment can be configured so as not to require any lumped constant elements connected to a ground plane and any through holes connecting this lumped constant element and the ground plane, which do not hinder high-frequency adaptation, so that a high-frequency filter having frequency characteristics as designed can be obtained.

As described above, the high-frequency filter of the present embodiment becomes a high-frequency filter that does not require any lumped constant elements and through holes that hinder high-frequency adaptation, making it possible to realize high-frequency adaptation. Besides, the through hole occupies a relatively large area on a dielectric substrate, so the high-frequency filter that does not require any through holes allows a degree of freedom in design to increase and can also be made more compact.

### Embodiment 2

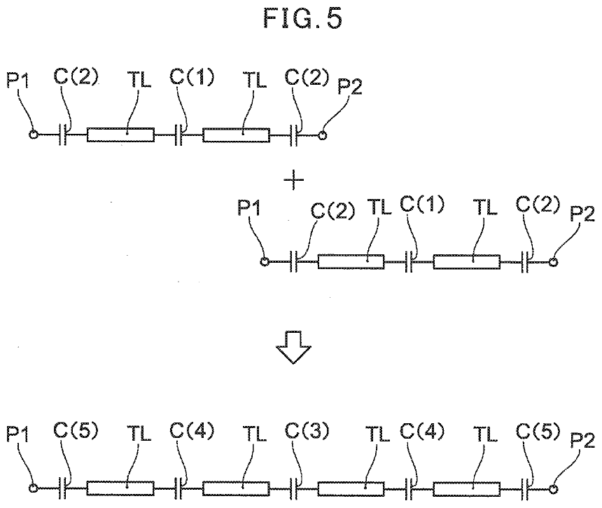

Next, Embodiment 2 of the present invention will be described. In the above-described Embodiment 1, the case is described where three capacitors, which are lumped constant elements, are connected in series between the transmission lines connected to the first terminal P1 and the second terminal P2, respectively. However, in the present invention, the number of capacitors, which are lumped constant elements, can be 2n−1 (n is an integer of 3 or more). FIG. 5 is an explanatory view of a high-frequency filter as a high-pass filter of Embodiment 2 of the present invention, and shows an equivalent circuit of the high-frequency filter as the high-pass filter configured by connecting the high-frequency filters described in Embodiment 1 in two-stage cascade connection. As shown in FIG. 5, the high-frequency filter of the present embodiment is a matched high-pass filter, in which 2n−1 (here, n is 3), i.e., five capacitors are connected in series between transmission lines connected to a first terminal P1 and a second terminal P2 that serve as an input terminal or an output terminal for a high-frequency signal, respectively. The five capacitors are composed of one capacitor C(3) and capacitors C(4) and C(5) connected to both ends of the capacitor C(3) in this order. The first terminal P1 and the second terminal P2 are connected to the capacitors C(5), respectively, by the transmission line having a characteristic impedance of Z₀. The five capacitors are connected to each other by the transmission line TL having the line length of λ/4 and the characteristic impedance of Z₀.

The high-frequency filter of the present embodiment has a configuration in which the high-frequency filters described in the above-described Embodiment 1 are connected in two-stage cascade connection, and capacitances C₃ to C₅ of the capacitors C(3) to C(5) of the high-frequency filter shown in FIG. 5 are determined in the same manner as in the above-described Embodiment 1.

As a result, the following relations are derived:

$$C 3 = C 2 / 2 = 1 / 2 ( 2 π \cdot {f}_{0} \cdot {Z}_{0} )$$

$$C 4 = C 5 = C 1 = 1 / ( 2 π \cdot {f}_{0} \cdot {Z}_{0} )$$

In this way, for the respective capacitances C₃ to C₅ of the capacitors C(3) to C(5) of the high-frequency filter of the present embodiment, the capacitance C3 of the third capacitor C(3) from the first terminal P1 becomes half a value of the capacitances C4 and C5 of the capacitors C(4) and C(5). Besides, the capacitance C3 corresponds to the capacitance C(H2) described in the first embodiment of the present invention in (1) mentioned above, and the capacitances C4 and C5 correspond to the capacitance C(H3) described in the first embodiment of the present invention in (1) mentioned above.

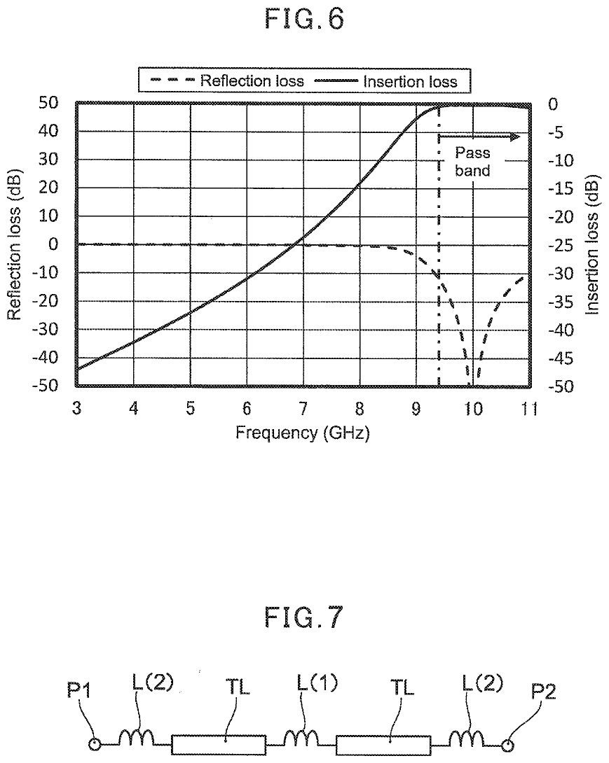

FIG. 6 is a characteristic diagram showing frequency characteristics of a reflection loss and an insertion loss of the high-frequency filter of the present embodiment in which a frequency f₀, at which a reflection loss of a passband frequency is minimized, is set to 10 GHz. In FIG. 6, the dashed line indicates a frequency characteristic of the reflection loss, and the solid line indicates a frequency characteristic of the insertion loss. When the frequency, at which the insertion loss drops by 0.5 dB, is defined as a cutoff frequency, the cutoff frequency becomes 9.4 GHz in the example shown in FIG. 6, and it can be confirmed that a high-frequency filter that functions as a high-pass filter is formed. The high-frequency filter of the present embodiment has frequency characteristics in which the insertion loss changes sharply in a stopband, as compared with the high-frequency filter described in Embodiment 1.

Besides, in the high-frequency filter of the present embodiment, the number of capacitors is not limited to five, but is set to 2n−1 (n is an integer of 3 or more), and the capacitance of the 2x−1-th (x is an integer from 2 to (n−1)) capacitor from the first terminal P1 is set to half a value of a predetermined capacitance of a capacitor other than the 2x−1-th capacitor from the first terminal P1, so that a high-frequency filter is configured. More specifically, if the number of capacitors is seven, capacitances of the third and fifth capacitors from the first terminal become half a value of a predetermined capacitance of the other capacitors, and if the number of capacitors is nine, capacitances of the third, fifth, and seventh capacitors from the first terminal become half a value of a predetermined capacitance of the other capacitors.

As described above, the high-frequency filter of the present embodiment does not require any lumped constant elements and any through holes that hinder high-frequency adaptation, thus, becomes a high-frequency filter having frequency characteristics as designed, making it possible to realize high-frequency adaptation. Besides, the through hole occupies a relatively large area on a dielectric substrate, so the high-frequency filter that does not require any through holes allows a degree of freedom in design to increase and can also be made more compact.

### Embodiment 3

Next, Embodiment 3 of the present invention will be described. In the present embodiment, the number of lumped constant elements is 2n−1 (here n is 2), that is, three, and all of the lumped constant elements become high-frequency filters composed of inductors. FIG. 7 is an explanatory view of a high-frequency filter as a low-pass filter of Embodiment 3 of the present invention, and is an equivalent circuit of the high-frequency filter as the low-pass filter. As shown in FIG. 7, the high-frequency filter of the present embodiment is a matched low-pass filter, in which three inductors are connected in series between transmission lines connected to a first terminal P1 and a second terminal P2 that serve as an input terminal or an output terminal for a high-frequency signal, respectively. The three inductors are composed of one inductor L(1) and two inductors L(2) connected to both ends of the inductor L(1). The first terminal P1 and the second terminal P2 are connected to the inductors C(2), respectively, by the transmission line having the characteristic impedance of Z₀. The three inductors are connected to each other by the transmission line TL having the line length of λ/4 and the characteristic impedance of Z₀.

Here, inductances L1 and L2 of the inductors L(1) and L(2) are determined in the same manner as in the above-described Embodiment 1.

As a result, the following relations are derived:

$$L 1 = L = {Z}_{0} / ( 2 π \cdot {f}_{0} )$$

$$L 2 = L 1 = {Z}_{0} / ( 2 π \cdot {f}_{0} )$$

In this way, the respective inductances L1 and L2 of the inductors L(1) and L(2) of the high-frequency filter of the present embodiment become equal values. Besides, the inductances L1 and L2 correspond to the inductance L (L1) described in the second embodiment of the present invention mentioned in (2) above.

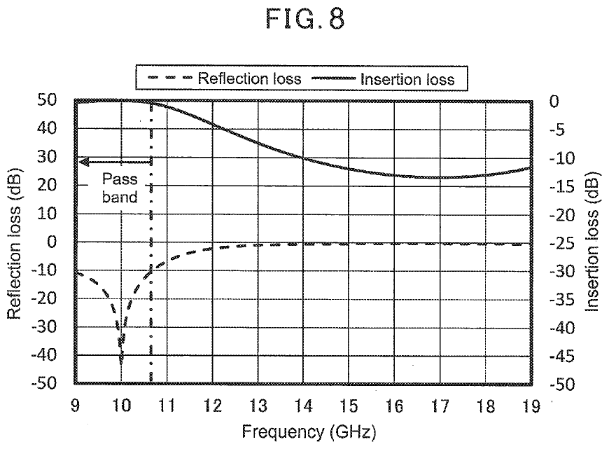

FIG. 8 is a characteristic diagram showing frequency characteristics of a reflection loss and an insertion loss of the high-frequency filter of the present embodiment in which a frequency f₀, at which a reflection loss of a passband frequency is minimized, is set to 10 GHz. In FIG. 8, the dashed line indicates a frequency characteristic of the reflection loss, and the solid line indicates a frequency characteristic of the insertion loss. When the frequency, at which the insertion loss drops by 0.5 dB, is defined as a cutoff frequency, the cutoff frequency becomes 10.7 GHz in the example shown in FIG. 8, and it can be confirmed that a high-frequency filter that functions as a low-pass filter is formed.

Moreover, the high-frequency filter of the present embodiment can be configured so as not to require any lumped constant elements connected to a ground plane and any through holes connecting this lumped constant element and the ground plane, which do not hinder high-frequency adaptation, so that a high-frequency filter having frequency characteristics as designed can be obtained.

As described above, the high-frequency filter of the present embodiment also becomes a high-frequency filter that does not require any lumped constant elements and any through holes that hinder high-frequency adaptation, making it possible to realize high-frequency adaptation. Besides, the through hole occupies a relatively large area on a dielectric substrate, so the high-frequency filter that does not require any through holes allows a degree of freedom in design to increase and can also be made more compact.

### Embodiment 4

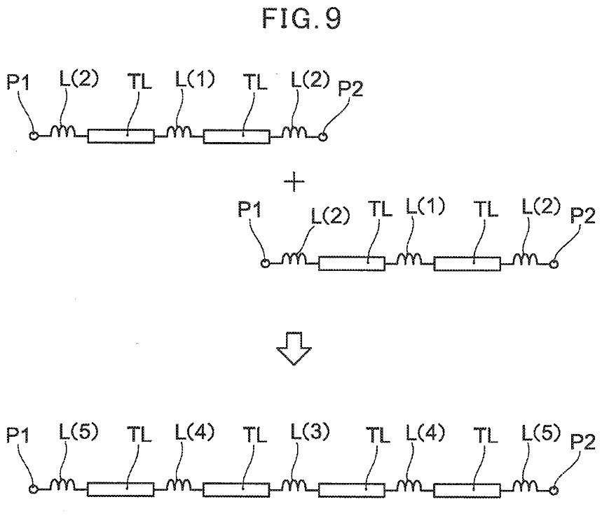

Next, Embodiment 4 of the present invention will be described. In the above-described Embodiment 3, the case is described where three inductors, which are lumped constant elements, are connected in series between the transmission lines connected to the first terminal P1 and the second terminal P2, respectively. However, in the present invention, the number of inductors, which are lumped constant elements, can be 2n−1 (n is an integer of 3 or more). FIG. 9 is an explanatory view of a high-frequency filter as a low-pass filter of Embodiment 4 of the present invention, and shows an equivalent circuit of the high-frequency filter as the low-pass filter configured by connecting the high-frequency filters described in Embodiment 3 in two-stage cascade connection. As shown in FIG. 9, the high-frequency filter of the present embodiment is a matched low-pass filter, in which 2n−1 (here, n is 3), i.e., five inductors are connected in series between transmission lines connected to a first terminal P1 and a second terminal P2 that serve as an input terminal or an output terminal for a high-frequency signal, respectively. The five inductors are composed of one inductor L(3) and inductors L(4) and L(5) connected to both ends of the inductor L(3) in this order. The first terminal P1 and the second terminal P2 are connected to the inductors L(5), respectively, by the transmission line having the characteristic impedance of Z₀. Moreover, the five inductors are connected to each other by the transmission line TL having the line length of λ/4 and the characteristic impedance of Z₀.

The high-frequency filter of the present embodiment has a configuration in which the high-frequency filters described in the above-described Embodiment 3 are connected in two-stage cascade connection, and inductances L3 to L5 of the inductors L(3) to L(5) of the high-frequency filter shown in FIG. 9 are determined in the same manner as in the above-described Embodiment 1.

As a result, the following relations are derived:

$$L 3 = 2 \times L 2 = 2 {Z}_{0} / ( 2 π \cdot {f}_{0} )$$

$$L 4 = L 5 = L 1 = {Z}_{0} / ( 2 π \cdot {f}_{0} )$$

In this way, for the respective inductances L3 to L5 of the inductors L(3) to L(5) of the high-frequency filter of the present embodiment, the inductance L3 of the third inductor L(3) from the first terminal P1 becomes twice a value of the inductances L4 and L5 of the inductors L(4) and L(5). Besides, the inductance L3 corresponds to the inductance L(L2) described in the second embodiment of the present invention in (2) mentioned above, and the inductances L4 and L5 correspond to inductance L(H3) described in the second embodiment of the present invention in (2) mentioned above.

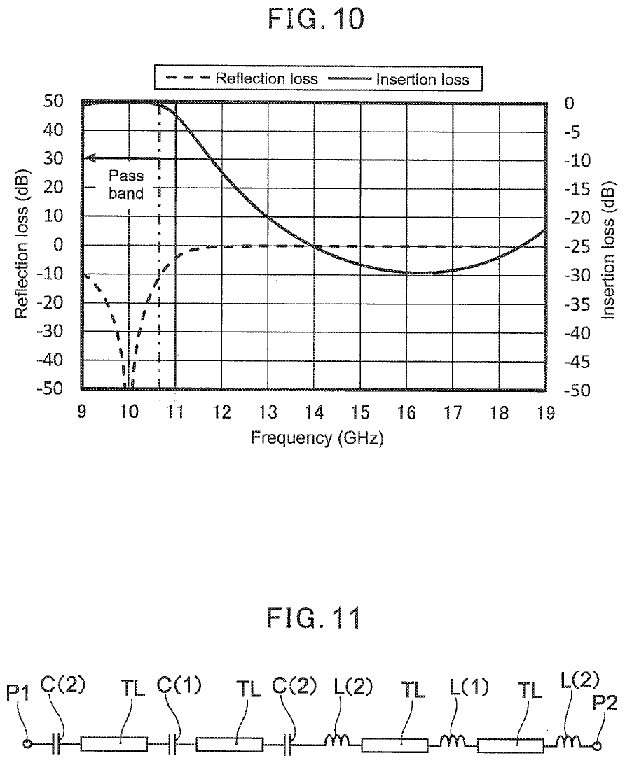

FIG. 10 is a characteristic diagram showing frequency characteristics of a reflection loss and an insertion loss of the high-frequency filter of the present embodiment in which a frequency f₀, at which a reflection loss of a passband frequency is minimized, is set to 10 GHz. In FIG. 10, the dashed line indicates a frequency characteristic of the reflection loss, and the solid line indicates a frequency characteristic of the insertion loss. When the frequency, at which the insertion loss drops by 0.5 dB, is defined as a cutoff frequency, the cutoff frequency becomes 10.7 GHz in the example shown in FIG. 10, and it can be confirmed that a high-frequency filter that functions as a low-pass filter is formed. The high-frequency filter of the present embodiment has frequency characteristics in which the insertion loss changes sharply in a stopband, as compared with the high-frequency filter described in Embodiment 3.

Besides, in the high-frequency filter of the present embodiment, the number of inductors is not limited to five, but is set to 2n−1 (n is an integer of 3 or more), and the inductance of the 2x−1-th (x is an integer from 2 to (n−1)) inductor from the first terminal P1 is set to twice a value of a predetermined inductance of an inductor other than the 2x−1-th inductor from the first terminal P1, so that a high-frequency filter is configured. More specifically, if the number of inductors is seven, inductances of the third and fifth inductors from the first terminal become twice a value of a predetermined inductance of the other inductors, and if the number of inductors is nine, inductances of the third, fifth, and seventh inductors from the first terminal become twice a value of a predetermined inductance of the other inductors.

As described above, the high-frequency filter of the present embodiment does not require any lumped constant elements and any through holes that hinder high-frequency adaptation, thus, becomes a high-frequency filter having frequency characteristics as designed, making it possible to realize high-frequency adaptation. Besides, the through hole occupies a relatively large area on a dielectric substrate, so the high-frequency filter that does not require any through holes allows a degree of freedom in design to increase and can also be made more compact.

### Embodiment 5

Next, Embodiment 5 of the present invention will be described. A band-pass filter can be configured by connecting in series the high-pass filter described in the above-described Embodiments 1 and 2 and the low-pass filter described in the above-described Embodiments 3 and 4. FIG. 11 is an explanatory view of a high-frequency filter as a band-pass filter of Embodiment of the present invention, and is an equivalent circuit of the high-frequency filter as the band-pass filter. As shown in FIG. 11, the high-frequency filter of the present embodiment is a matched band-pass filter, in which a high-pass filter having the configuration described in Embodiment 1 and a low-pass filter having the configuration described in Embodiment 3 are connected in series, and the capacitor C(2) connected third from the terminal P1 and the inductor L(2) adjacent thereto are connected by the transmission line having the characteristic impedance of Z₀.

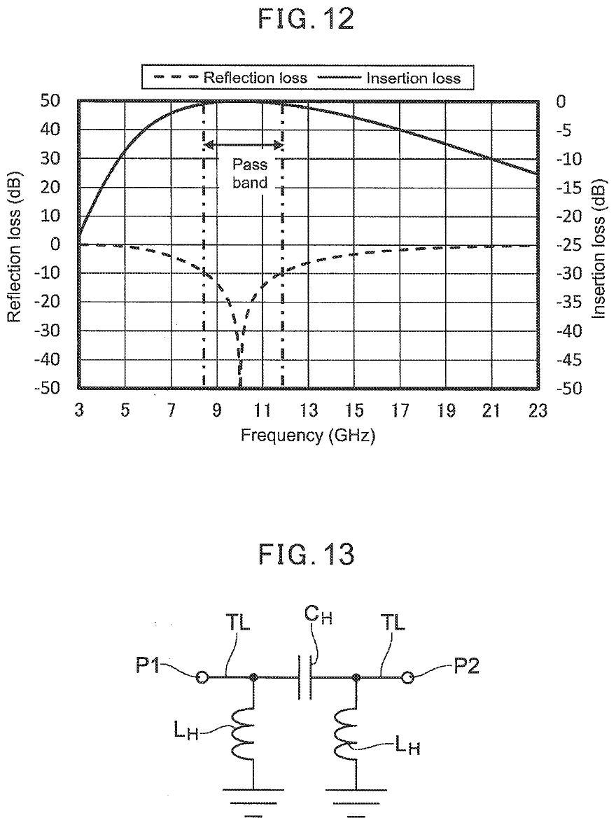

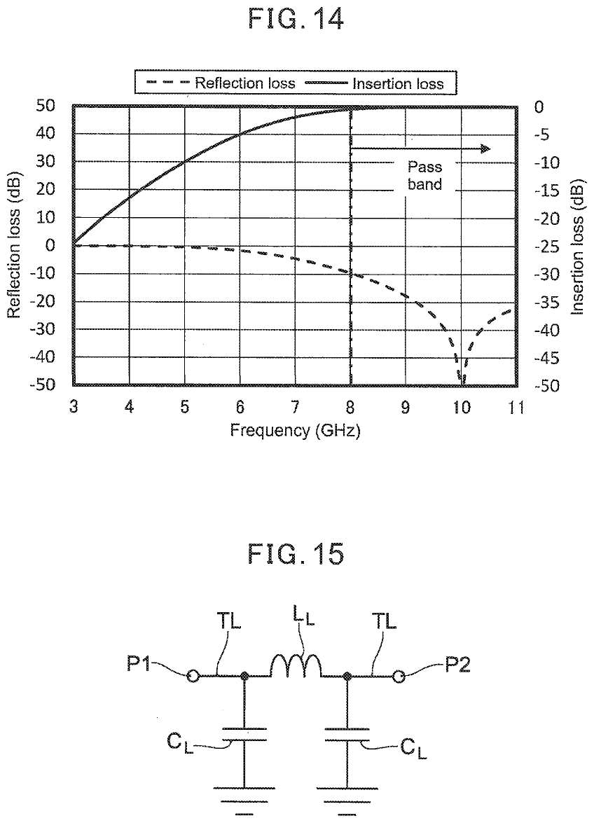

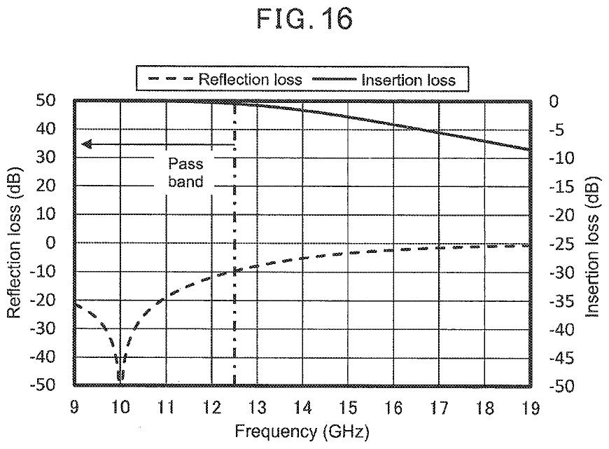

FIG. 12 is a characteristic diagram showing frequency characteristics of a reflection loss and an insertion loss of the high-frequency filter of the present embodiment in which a high-pass filter and a low-pass filter are connected in series, where a frequency f₀, at which a reflection loss of a passband frequency is minimized, is set to 10 GHz. In FIG. 12, the dashed line indicates a frequency characteristic of the reflection loss, and the solid line indicates a frequency characteristic of the insertion loss. When the frequency, at which the insertion loss drops by 0.5 dB, is defined as a cutoff frequency, the passband becomes 8.4 GHz to 11.9 GHz in the example shown in FIG. 12, and it can be confirmed that a high-frequency filter that functions as a band-pass filter is formed.

Moreover, the high-frequency filter of the present embodiment can be configured so as not to require any lumped constant elements connected to a ground plane and any through holes connecting this lumped constant element and the ground plane, which do not hinder high-frequency adaptation, so that a high-frequency filter having frequency characteristics as designed can be obtained.

As described above, the high-frequency filter of the present embodiment also becomes a high-frequency filter that does not require any lumped constant elements and any through holes that hinder high-frequency adaptation, making it possible to realize high-frequency adaptation. Besides, the through hole occupies a relatively large area on a dielectric substrate, so the high-frequency filter that does not require any through holes allows a degree of freedom in design to increase and can also be made more compact.

Although the embodiments of the high-frequency filter of the present invention have been described above, it is needless to say that the present invention is not limited to the above-described embodiments. For example, the number of capacitors in a high-pass filter and the number of inductors in a low-pass filter, which are connected to constitute a band-pass filter, are not limited to three, respectively, and there is no problem if the number of capacitors constituting the high-pass filter and the number of inductors constituting the low-pass filter are different. A high-frequency transmission line is not limited to a microstrip line, but can be a grounded coplanar transmission line.

### REFERENCE SIGNS LIST

P1. First terminal
P2. Second terminal
C_{H}, C_{L}, C(1) to C(5). Capacitor
L_{H}, L_{L}, L(1) to L(5). Inductor
TL. Transmission line

1. A high-frequency filter, comprising, on a surface of a dielectric substrate,
transmission lines connected to a first terminal and a second terminal, respectively, and
2n−1 (n is an integer of 2 or more) lumped constant elements connected in series between the transmission lines,
one end of a first lumped constant element being connected to the first terminal,
one end of a 2n−1-th lumped constant element being connected to the second terminal, and
a second to a 2n−2-th lumped constant elements being connected between the first lumped constant element and the 2n−1-th lumped constant element,
wherein all of the 2n−1 lumped constant elements are composed of capacitors, the capacitors being connected to each other by a transmission line having a line length of λ/4 (λ is a wavelength within a transmission line corresponding to a frequency f₀ at which a reflection loss of a passband frequency is minimized) and a characteristic impedance of Z₀, and
wherein
(i) when n is 2, a capacitance C(H1) of the capacitors is given by:
C(H1)=1/(2π·f₀·Z₀), and
(ii) when n is 3 or more, a capacitance C(H2) of a 2x−1-th (x is an integer from 2 to (n−1)) one of the capacitors from the first terminal is given by:
C(H2)=½(2π·f₀·Z₀), and
a capacitance C(H3) of the capacitors other than the 2x−1-th one from the first terminal is given by:
$$C ( H 3 ) = 1 / ( 2 π \cdot {f}_{0} \cdot {Z}_{0} ) .$$

2. A high-frequency filter, comprising, on a surface of a dielectric substrate,
transmission lines connected to a first terminal and a second terminal, respectively, and
2n−1 (n is an integer of 2 or more) lumped constant elements connected in series between the transmission lines,
one end of a first lumped constant element being connected to the first terminal,
one end of a 2n−1-th lumped constant element being connected to the second terminal, and
a second to a 2n−2-th lumped constant elements being connected between the first lumped constant element and the 2n−1-th lumped constant element,
wherein all of the 2n−1 lumped constant elements are composed of inductors, the inductors being connected to each other by a transmission line having a line length of λ/4 (λ is a wavelength within a transmission line corresponding to a frequency f₀ at which a reflection loss of a passband frequency is minimized) and a characteristic impedance of Z₀, and
wherein
(i) when n is 2, an inductance L(L1) of the inductors is given by:
L(L1)=Z₀/(2π·f₀), and
(ii) when n is 3 or more, an inductance L(L2) of a 2x−1-th (x is an integer from 2 to (n−1)) one of the inductors from the first terminal is given by:
L(L2)=2Z₀/(2π·f₀), and
an inductance L(L3) of the inductors other than the 2x−1-th one from the first terminal is given by:
$$L ( L 3 ) = {Z}_{0} / ( 2 π \cdot {f}_{0} ) .$$

3. A high-frequency filter, wherein a high-frequency filter of claim 1 and a high-frequency filter of claim 2 are connected in series.
